(19) United States
(12) Patent Application Publication
(10) Pub. No.: US 2025/0011915 A1
(43) Pub. Date: Jan. 9, 2025

(54) METAL MASK

(71) Applicant: DARWIN PRECISIONS CORPORATION, Hsinchu County (TW)

(72) Inventors: KANG-HSIANG LIU, Hsinchu County (TW); Chi-Wei Lin, Hsinchu County (TW)

(21) Appl. No.: 18/416,909

(22) Filed: Jan. 19, 2024

(30) Foreign Application Priority Data
Jul. 7, 2023 (TW) 112125500

(51) Int. Cl. C23C 14/04; C03C 17/00; C23C 14/24

(52) U.S. Cl. CPC C23C 14/042; C23C 14/24; C03C 17/002; C03C 2218/34

(57) ABSTRACT

A metal mask includes a metal plate having an evaporation surface and a back surface and a plurality of through-holes. Each through-hole forms a first opening on the evaporation surface and a neck opening between the evaporation surface and the back surface. The first opening has two first long edges and two opposite first short edges. The neck opening has two second long edges and two second short edges. A ratio of a length of the second long edge to a length of the second short edge is equal to or greater than 2.5. A first angle is formed between a connecting line between the first long edge and the second long edge and the back surface, a second angle is formed between a connecting line between the adjacent first short edge and second short edge and the back surface, and the second angle is less than the first angle.

### FIELD OF THE INVENTION

The present invention relates to a metal mask, and in particular to a metal mask used in manufacturing a display panel.

### BACKGROUND OF THE INVENTION

An organic light-emitting diode (OLED) panel produced by applying an OLED technology is a main component of a display panel of a mobile phone in the market at present, and has advantages of self-luminescence, wide viewing angle, power saving, high efficiency, short response time, lightness, thinness, and the like.

The OLED panel structurally includes a glass substrate and an organic luminescent material layer on the glass substrate. The organic luminescent material layer mainly includes a plurality of luminescent patterns. The luminescent pattern is manufactured by using a fine metal mask (FMM) in combination with evaporation, and a material of the luminescent pattern is formed on the glass substrate. Therefore, the shape and distribution of the through-holes on the FMM determine the shape, size and configuration position of the luminescent pattern on the glass substrate, and the fineness of the luminescent pattern is further affected in combination with the way of actual evaporation, thereby affecting the display quality of the OLED panel.

### SUMMARY OF THE INVENTION

The present invention provides a metal mask, which has a relatively small shadow effect during evaporation.

In order to achieve the above advantages, an embodiment of the present invention provides a metal mask, wherein the metal plate has an evaporation surface and a back surface opposite to each other and a plurality of through-holes extending from the evaporation surface to the back surface, each of the through-holes forms a first opening on the evaporation surface and forms a neck opening between the evaporation surface and the back surface, the first opening tapers towards the neck opening and has two opposite first long edges and two opposite first short edges, the two first short edges are connected between the two first long edges, the neck opening has two opposite second long edges and two opposite second short edges, the two second short edges are connected between the two second long edges, and a ratio of a length of the second long edge to a length of the second short edge is equal to or greater than 2.5. Where, a first angle is formed between a connecting line between the first long edge and the second long edge and the back surface, a second angle is formed between a connecting line between the first short edge and the second short edge and the back surface, and the second angle is less than the first angle.

In an embodiment, each of the through-holes forms a second opening on the back surface, an outline of the second opening corresponds to an outline of the neck opening so that the second opening has two opposite third long edges and two opposite third short edges, the second opening tapers towards the neck opening, and an opening size of the neck opening is less than opening sizes of the first opening and the second opening.

In an embodiment, according to the metal mask, in a direction along an opening direction of the through-hole, a thickness distance exists between the third short edge and the second short edge; in a direction perpendicular to the opening direction, an expansion distance exists between the third short edge and the second short edge; the thickness distance is less than or equal to 4 μm, and the expansion distance is less than or equal to 2 μm.

In an embodiment, the through-holes are arranged along an extension direction parallel to the third long edge, a thickness of the metal plate is between 18 μm and 27 μm, and a spacing between two adjacent third short edges of two adjacent through-holes in the extension direction is between 15 μm and 45 μm.

In an embodiment, the thickness is between 18 μm and 22 μm, and the spacing is between 15 μm and 30 μm.

In an embodiment, the difference between the second angle and the first angle is greater than or equal to 5 degrees.

In an embodiment, the difference between the second angle and the first angle is between 5 degrees and 10 degrees.

As explained above, the metal mask of the present invention has a plurality of through-holes with the length-width ratio equal to or greater than 2.5, the shapes of the first openings formed by the through-holes on the evaporation surface are designed, and the angle between the connecting line between the first short edge and the second short edge and the back surface on the evaporation surface side is less than the angle between the connecting line between the first long edge and the second long edge and the back surface, so that the influence of the shadow effect can be reduced when products are manufactured.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a schematic diagram of a metal mask according to an embodiment of the present invention;

FIG. 2A is a schematic diagram of a through-hole part in an embodiment of the present invention;

FIG. 2B is a schematic diagram of a through-hole part in another embodiment of the present invention;

FIG. 3A is a schematic diagram of a through-hole, taken along the line A-A in FIG. 2A;

FIG. 3B is a schematic diagram of the through-hole, taken along the line B-B in FIG. 2A;

FIG. 4 is a flow diagram of a manufacturing method of the metal mask of FIG. 1 in an embodiment; and

FIG. 5 is a schematic design diagram for manufacturing one of photomasks of the metal masks in the manufacturing method of FIG. 4.

### DETAILED DESCRIPTION OF PREFERRED EMBODIMENTS

Terms used in the description of the embodiments of the present invention, for example, orientation or position relation such as “above” and “below” are described according to the orientation or position relation shown in the drawings. The above terms are used for facilitating description of the present invention rather than limiting the present invention, i.e., indicating or implying that the mentioned elements have to have specific orientations and to be configured in the specific orientations. In addition, terms such as “first” and “second” involved in the description or claims are merely used for naming the elements or distinguishing different embodiments or ranges rather than limiting the upper limit or lower limit of the quantity of the elements.

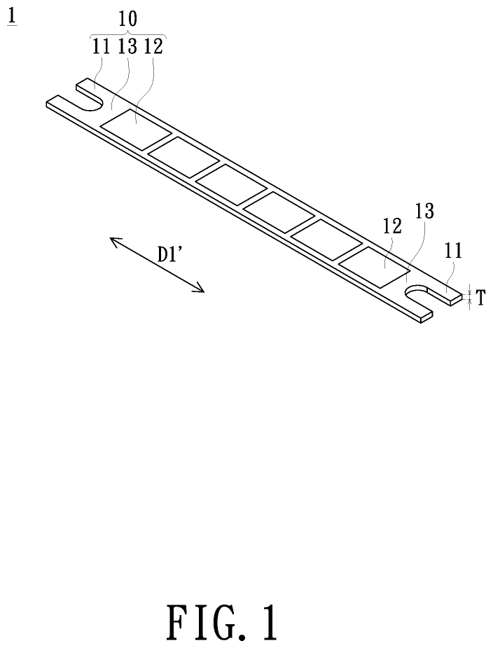

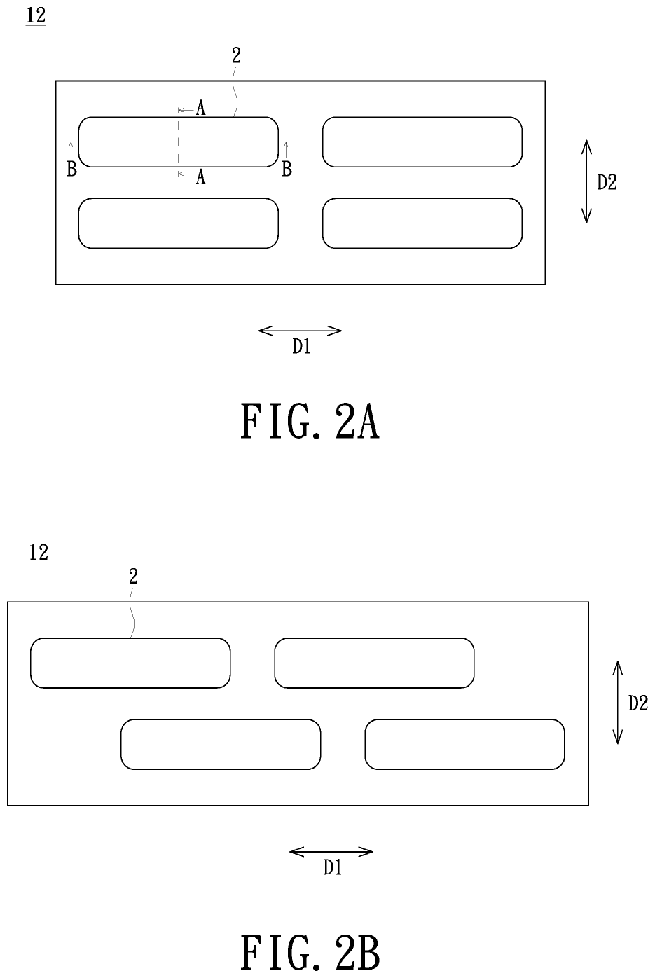

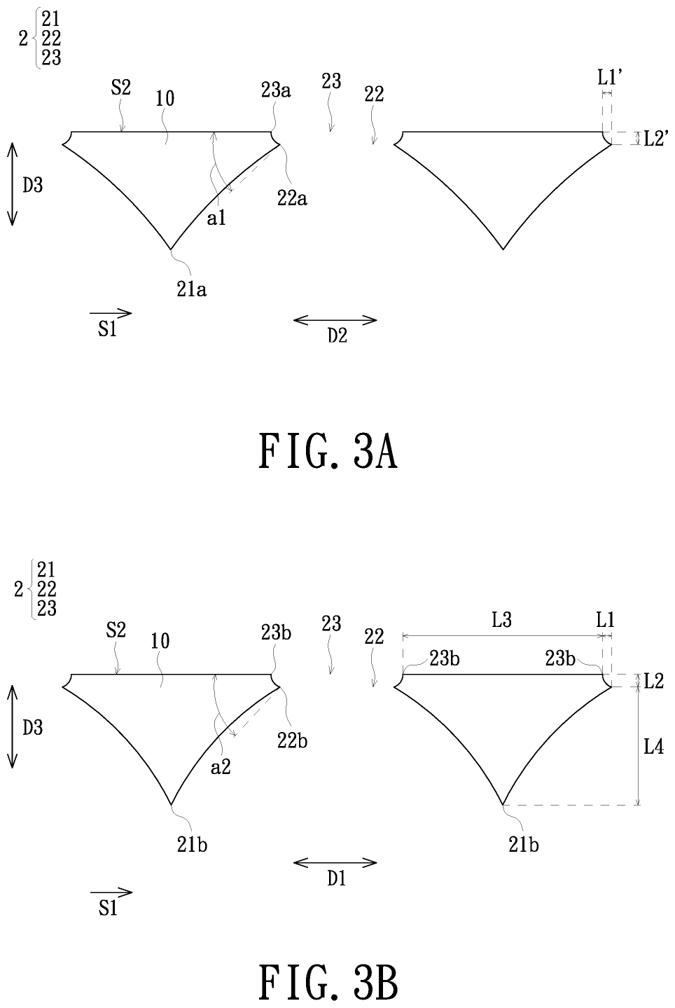

FIG. 1 is a schematic diagram of a metal mask according to an embodiment of the present invention. FIG. 2A is a schematic diagram of a through-hole part in an embodiment of the present invention. FIG. 3A is a schematic diagram of a through-hole, taken along the line A-A in FIG. 2A. FIG. 3B is a schematic diagram of the through-hole, taken along the line B-B in FIG. 2A. FIG. 1 to FIG. 3B are only schematic and not drawn to actual scale, and S1 in FIG. 3A and FIG. 3B only illustrates a position where an evaporation surface S1 is located, and does not refer to the evaporation surface S1.

As shown in FIG. 1, FIG. 2A, FIG. 3A and FIG. 3B, a metal mask 1 in an embodiment of the present invention includes a metal plate 10. The metal plate has an evaporation surface S1 and a back surface S2 opposite to each other and a plurality of through-holes 2 extending from the evaporation surface S1 to the back surface S2. Each of the through-holes 2 forms a first opening 21 on the evaporation surface S1 and forms a neck opening 22 between the evaporation surface S1 and the back surface S2. The first opening 21 tapers towards the neck opening 22 and has two opposite first long edges 21a and two opposite first short edges 21b. The two first short edges 21b are connected between the two first long edges 21a. The neck opening 22 has two opposite second long edges 22a and two opposite second short edges 22b. The two second short edges 22b are connected between the two second long edges 22a, and a ratio of a length of the second long edge 22a to a length of the second short edge 22b is equal to or greater than 2.5. Where, a first angle a1 (see FIG. 3A) is formed between a connecting line between the first long edge 21a and the second long edge 22a and the back surface S2, a second angle a2 (see FIG. 3B) is formed between a connecting line between the adjacent first short edge 21b and second short edge 22b and the back surface S2, and the second angle a2 is less than the first angle a1.

As shown in FIG. 1 and FIG. 3A, the metal mask 1 (metal plate 10) is, for example, elongated, and made of a nickel-iron alloy, and a thickness T of the metal mask 1 is, for example, between 18 μm and 27 μm. Clamping parts 11 are disposed at two opposite ends of the metal mask 1 along a long axis direction D1′. The clamping parts 11 are adapted to connect a clamp (not shown) when the metal mask 1 is used. A through-hole part 12 is disposed between the two clamping parts 11, and through-holes 2 are formed in the through-hole part 12 (see FIG. 2A or FIG. 2B). For example, the metal mask 1 is also provided with two welding parts 13 between the clamping parts 11 at the two sides and the through-hole part 12 in the center. The welding parts 13 are adapted to be welded with a frame (not shown) when the metal mask 1 is used.

In this embodiment, the long axis direction D1 of the through-hole 2 is, for example, the same as the long axis direction D′ of the metal plate 10, but it is not limited to this. As shown in FIG. 2A, in this embodiment, for example, the through-holes 2 are arranged side by side in the long axis direction D1 and a short axis direction D2 of the through-holes 2, but it is not limited to this. For example, in another embodiment shown in FIG. 2B, the through-holes 2 are arranged side by side in the same line along the long axis direction D1 and staggered in the short axis direction D2, and the detailed arrangement in the short axis direction D2 may depend on a pattern of a luminescent material (not shown) to be manufactured on a substrate (not shown) of a display panel. The display panel above is, for example, an OLED panel or other kinds of self-luminous display panels, but it is not limited to this.

As shown in FIG. 2A to FIG. 3B, in this embodiment, each of the through-holes 2 in the metal plate 10 forms, for example, a second opening 23 on the back surface S2 (that is, the surface facing the substrate when in use). The outline of the second opening 23 corresponds to the outline of the neck opening 22 so that the second opening 23 has two opposite third long edges 23a and two opposite third short edges 23b. The second opening 23 tapers towards the neck opening 22 so that the opening size of the neck opening 22 is less than the opening sizes of the first opening 21 and the second opening 23. The first opening 21, the second opening 23 and the neck opening 22 are, for example, rectangular corresponding to the shape of the through-hole 2, and the directions of long axes and the directions of short axes of the first opening 21, the second opening 23 and the neck opening 22 are the same (that is, the long axis direction D1 and the short axis direction D2). In addition, the wall surfaces of the first opening 21 and the second opening 23 are, for example, arc-shaped, and are, for example, arcs with gradually changing curvatures, but it is not limited to this.

In an embodiment of the present invention, the through-holes 2 are arranged along an extension direction parallel to the third long edge 23a (that is, the long axis direction D1, and also the extension directions of the first long edge 21a and the second long edge 22a). The thickness T (see FIG. 1) of the metal plate 10 is, for example, between 18 μm and 27 μm, and the spacing L3 between two adjacent third short edges 23b of two adjacent through-holes 2 in the extension direction (the long axis direction D1, see FIG. 3B) is, for example, between 15 μm and 45 μm. In some embodiments, the thickness T is, for example, between 18 μm and 22 μm, and the spacing L3 is, for example, between 15 μm and 30 μm. With respect to the specific difference between the second angle a2 and the first angle a1, the difference between the second angle a2 and the first angle a1 is, for example, greater than or equal to 5 degrees; and in some embodiments, the difference between the second angle a2 and the first angle a1 is, for example, between 5 and 10 degrees.

Refer to the following description for the design relationship among the thickness T, the spacing L3, the first angle a1 and the second angle a2.

Referring to FIG. 3A and FIG. 3B, when the metal mask 1 is performed with evaporation, the evaporation material is fed into the through-hole 2 from the side where the evaporation surface S1 is located, and the evaporation material is attached to the substrate (not shown) on the side where the back surface S2 is located. Therefore, in order to manufacture a high-quality display panel, it is expected that the cross-sectional area of the first opening 21 is, for example, larger than those of the second opening 23 and the neck opening 22, to allow more luminescent materials to be attached to the substrate during processing. Meanwhile, it is also expected that the neck opening 22 is close to the back surface S2 so that a pattern (not shown) of the luminescent material formed on the substrate after evaporation is close to the size and shape of the neck opening 22. Specifically, it is expected that the plate thickness between the second opening 23 (whether on the third long edge 23a or the third short edge 23b) along the opening direction D3 of the through-hole 2 and the neck opening 22 (that is, the thickness distance L2 between the second opening 23 and the neck opening 22 (see FIG. 3B), the thickness distance L2′ (see FIG. 3A)) will fall within the expected range of less than 4 μm. In addition, in the tapering direction of the through-hole 2, it is also expected that the expansion distance L1 (see FIG. 3B) and the expansion distance L1′ (see FIG. 3A) between an edge of the second opening 23 and an edge of the neck opening 22 fall within an expected range of less than 2 μm, so that the quality such as the shape and resolution of a luminescent pattern will be less affected by the shadow effect of the OLED panel during manufacturing.

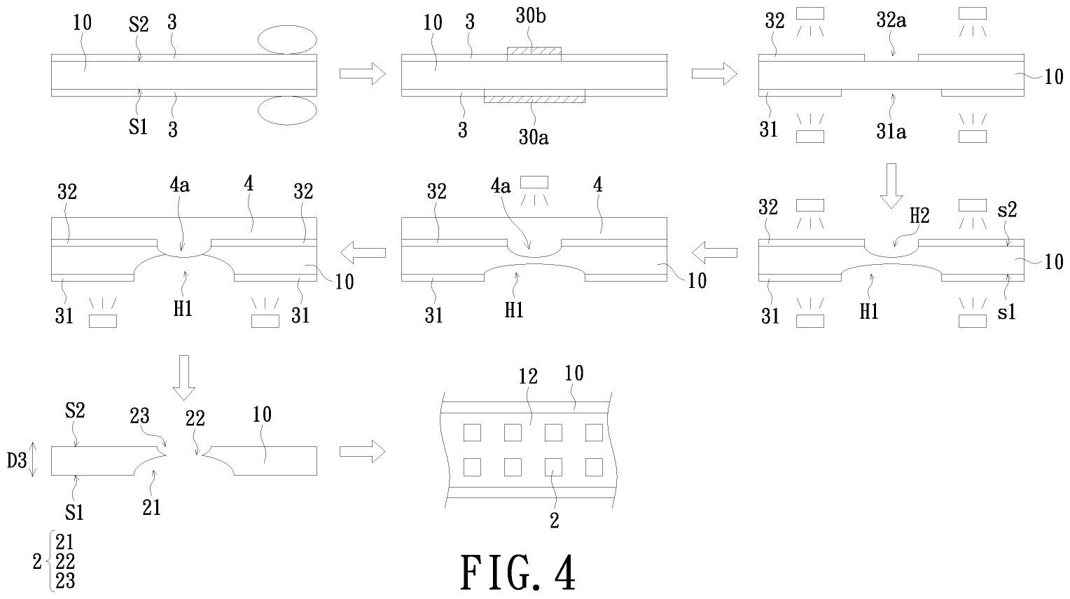

FIG. 4 is a flow diagram of a manufacturing method of the metal mask of FIG. 1 in an embodiment. Referring to FIG. 4, the manufacturing method of the metal mask 1 in FIG. 1 can be performed, for example, by the etching method as shown in FIG. 4, but it is not limited to this. The detailed flow of the method in FIG. 4 is as follows.

First, referring to the schematic diagram in the top row in FIG. 4, a metal plate 10 is provided, and a photoresist 3 is coated on the evaporation surface S1 and the back surface S2. The photoresist material 3 is, for example, a negative photoresist, but it is not limited to this. Next, for example, a photomask 30a and a photomask 30b respectively cover the photoresists 3 on the evaporation surface S1 and the back surface S2, and are exposed. Then the unexposed photoresist 3 is removed by development, and therefore the photoresist 3 on the evaporation surface S1 not covered by the photomask 30a forms a first patterned photoresist layer 31 on the evaporation surface S1, and the photoresist 3 on the back surface S2 not covered by the photomask 30b forms a second patterned photoresist layer 32 on the back surface S2. The first patterned photoresist layer 31 has a first photoresist opening 31a corresponding to the shape of the photomask 30a, and the second patterned photoresist layer 32 has a second photoresist opening 32a corresponding to the shape of the photomask 30b. In this embodiment, the cross-sectional area of the second photoresist opening 32a is, for example, less than that of the first photoresist opening 31a, but it is not limited to this.

Next, referring to the schematic diagram in the middle row in FIG. 4, a primary etching operation is performed on the metal plate 10. Because the metal plate 10 is not covered by the first patterned photoresist layer 31 and the second patterned photoresist layer 32 at the first photoresist opening 31a and the second photoresist opening 32a, the evaporation surface S1 and the back surface S2 of the metal plate 10 is etched to form a first transition opening H1 in the evaporation surface S1 and a second transition opening H2 in the back surface S2 at the same time.

Thereafter, a protective material is coated on the back surface S2 of the metal plate 10 to form a protective layer 4, and a part of the protective layer 4 forms a protrusion 4a protruding towards the evaporation surface S1 in the second photoresist opening 32a. The protective material is, for example, the photoresist, so that the protective layer 4 can be formed after exposure, but it is not limited to this. In other embodiments, the protective material is, for example, resin, which can be selected as required.

Next, a secondary etching operation is performed on the metal plate 10. In this operation, the metal plate 10 is not protected at the first photoresist opening 31a and thus is etched, so that the first transition opening H1 continues to expand towards the back surface S2 and contacts with the protrusion 4a.

Thereafter, referring to the schematic diagram in the bottom row of FIG. 4, the first patterned photoresist layer 31, the second patterned photoresist layer 32 and the protective layer 4 (including the protrusion 4a) are removed so as to form the first opening 21, the second opening 23, the neck opening 22 and the through-hole 2 in the metal plate 10, and to form the through-hole part 12 on the metal plate 10.

As can be seen from the above description and the schematic diagrams of FIG. 3A to FIG. 4, the first opening 21 is an opening formed by expanding the first transition opening H1 again after the secondary etching operation is performed. The second opening 23 is an opening formed at the second transition opening H2 after the primary etching operation is performed. In other words, the shape of the wall surface of the second opening 23 corresponds to the shape of the wall surface of a part of the second transition opening H2. The neck opening 22 is an opening formed when a front end of the expanded first transition opening H1 comes into contact with the protrusion 4a during the secondary etching operation. Furthermore, the wall surfaces of the first opening 21 and the second opening 23 manufactured by the manufacturing method of FIG. 4 are, for example, arc-shaped, and are, for example, arcs with gradually changing curvatures.

The cross-sectional area of the first opening 21 is, for example, greater than those of the second opening 23 and the neck opening 22, and the cross-sectional area of the neck opening 22 is, for example, less than those of the first opening 21 and the second opening 23. In addition, the etching rate when the etching operation is performed is affected by the sizes of the first photoresist opening 31a and the second photoresist opening 32a, the size of the first photoresist opening 31a is greater than that of the second photoresist opening 32a, and the metal plate 10 is subjected to secondary etching at the first opening 21. Therefore, it can be seen from FIG. 3B combined with FIG. 4 that in the opening direction D3 of the through-hole 2, the distance between the second short edge 22b of the neck opening 22 and the back surface S2 or the third short edge 23b (i.e., the thickness distance L2, see FIG. 3B) is less than a thickness distance L4 between the second short edge 22b of the neck opening 22 and the first short edge 21b of the first opening 21.

As can be seen from FIG. 3A to FIG. 4, the thickness distance L2, the thickness distance L2′, the expansion distance L1, and the expansion distance L1′ of the second opening 23 are all affected by the etching amount after the first transition opening H1 comes into contact with the protrusion 4a in the secondary etching operation. In actual etching, the etching rate of the first transition opening H1 is different in different directions. Specifically, the longitudinal etching rate along the opening direction D3 is greater than the transverse etching rate in the direction perpendicular to the opening direction D3, so that the higher the etching amount of the first transition opening H1 is, the smaller the first angle a1 and the second angle a2 of the first opening 21 are, and the closer the bottom of the first opening 21 (that is, the neck opening 22) is to the back surface S2. Based on the above characteristics, it can be observed that if the first angle a1 and the second angle a2 of the etched first opening 21 are smaller, the thickness distance L2, thickness distance L2′, expansion distance L1 and expansion distance L1′ of the second opening 23 will become smaller.

Referring to FIG. 3A and FIG. 3B, in addition, in this manufacturing method, it can be observed in practice that when the length-width ratio of the through-hole 2 (more precisely, the neck opening 22) is greater than or equal to 2.5, different etching amounts will be generated in different directions of the second opening 23 in an etching process. Specifically, in the same etching time, the expansion distance L1 generated by the second opening 23 in the long axis direction D1 is greater than the expansion distance L1′ generated in the short axis direction D2. Based on this phenomenon, the length-width ratio of the second opening 23 may change when the length-width ratio of the neck opening 22 predetermined to be manufactured is greater than or equal to 2.5. As a result, even if the expansion distance L1′ of the second opening 23 in the short axis direction D2 can fall within the expected range of less than 2 μm and the thickness distance L2′ can fall within the expected range of less than 4 μm, the expansion distance L1 and the thickness distance L2 of the second opening 23 do not necessarily fall within the aforementioned expected ranges in the long axis direction D1, and such a metal mask 1 will have a serious shadow effect in the long axis direction D1 when in use. In addition, the greater the length-width ratio of the neck opening 22 is, the more serious the shadow effect is.

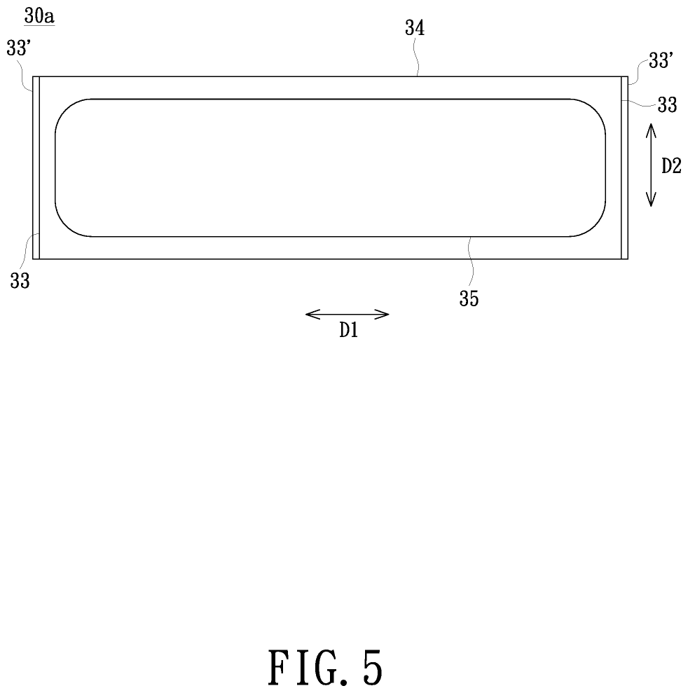

FIG. 5 is a schematic design diagram for manufacturing one of photomasks of the metal mask in the manufacturing method of FIG. 4. The length-width ratio in FIG. 5 is not drawn according to the actual ratio, and please refer to the text description for reference. Referring to FIG. 4 and FIG. 5, in order to solve the above problem, because the etching rate is affected by the shapes of the first photoresist opening 31a and the second photoresist opening 32a and the shapes of the first photoresist opening 31a and the second photoresist opening 32a are affected by the photomask 30a and the photomask 30b, in the embodiment illustrated in FIG. 4, the length-width ratio of the photomask 30a used for manufacturing the first photoresist opening 31a is adjusted slightly different from the actually expected length-width ratio of the through-hole 2 (more precisely, the neck opening 22).

Referring to FIG. 5, specifically, in order to manufacture the neck opening 22, a long edge 34 and a short edge 33 with sizes larger than the outline of the neck opening 22 can be provided around the predetermined pattern 35 corresponding to the outline of the neck opening 22, and then the shape of the photomask 30a is adjusted according to actual test results, for example, the length of the long edge 34 can be changed by moving the two short edges 33 of the photomask 30a to positions of the short edges 33′, the relationship between the first angle a1 and the second angle a2 is adjusted by changing the length-width ratio of the photomask 30a (and the corresponding first photoresist opening 31a) and changing the etching amounts in the long axis direction D1 and the short axis direction D2 per unit time.

Based on the above, when the etching operation with the length-width ratio equal to or greater than 2.5 is performed, the first photoresist opening 31a has different etching amounts in the long axis direction D1 and the short axis direction D2. In addition, the etching cross-sectional area is increased by increasing the distance of the first photoresist opening 31a in the long axis direction D1 when the photomask 30a shown in FIG. 5 is used, so that the second angle a2 of the first opening 21 manufactured by the above method in the long axis direction D1 is less than the first angle a1 of the first opening 21 in the short axis direction D2, the expansion distance L1 and the expansion distance L1′ of the second opening 23 are different, and the length-width ratio of the shape of the second opening 23 manufactured by the above method can be close to the predetermined length-width ratio of the shape of the neck opening 22, thereby reducing the influence of the shadow effect in the long axis direction.

Table 1 and Table 2 below show several groups of experimental results with the thickness distance L2 less than 4 μm and the expansion distance L1 less than 2 μm for the metal plates 10 with different thicknesses T (see FIG. 1), when the length-width ratio of the neck opening 22 is 3.5 (greater than 2.5). Table 1 is an experimental result table for the metal plates 10 with the thicknesses T of 25±2 μm, and Table 2 is an experimental result table for the metal plates 10 with the thicknesses T of 20±2 μm. The spacing L3 in Table 1 and Table 2 indicates the distance between two third short edges 23b along the long axis direction D1, and between two different first openings 21 of two adjacent through-holes 2 (see FIG. 3B).

TABLE 1

| | | | | The difference | | | The difference | | |
|---|---|---|---|---|---|---|---|---|---|
| | The difference | | | between the first | | | between the first | | |
| | between the first | | | angle a1 and the | | | angle a1 and the | | |
| | angle a1 and the | | | second angle a2 is | | | second angle a2 is | | |
| | second angle a2 is | | | approximately equal | | | approximately equal | | |
| | less than 5 degrees. | | | to 5 degrees. | | | to 10 degrees. | | |
| | Second | Expansion | | Second | Expansion | | Second | Expansion | |
| | angle a2/ | distance | | angle a2/ | distance | | angle a2/ | distance | |
| Spacing | first | L1/ | | first | L1/ | | first | L1/ | |
| L3 | angle | thickness | | angle | thickness | | angle | thickness | |
| (μm) | a1 | distance L2 | Result | a1 | distance L2 | Result | a1 | distance L2 | Result |
| 15 | 52.5/51.9 | 3.3/4.7 | Poor | 47.4/52.5 | 2.2/3.8 | Poor | 42.6/52.1 | 1.7/3.0 | Qualified |
| 20 | 53.0/52.5 | 2.8/4.5 | Poor | 47.5/52.9 | 2.0/3.6 | Barely | 41.9/52.3 | 1.5/2.9 | Qualified |
| | | | | | | satisfactory | | | |
| 25 | 51.8/52.2 | 2.5/4.2 | Poor | 48.0/53.1 | 1.9/3.4 | Barely | 42.9/53.1 | 1.3/2.3 | Qualified |
| | | | | | | satisfactory | | | |
| 30 | 52.6/53.1 | 2.2/4.0 | Poor | 46.8/52.5 | 1.7/3.1 | Qualified | | | Qualified |
| 35 | 52.3/52.7 | 2.0/3.8 | Barely | 47.7/52.9 | 1.5/2.8 | Qualified | | | Qualified |
| | | | satisfactory | | | | | | |
| 40 | 51.9/52.3 | 2.1/4.1 | Barely | 47.3/52.7 | 1.3/2.6 | Qualified | | | Qualified |
| | | | satisfactory | | | | | | |
| 45 | 52.8/52.8 | 1.9/3.7 | Barely | 47.3/51.9 | 1.1/2.4 | Qualified | | | Qualified |
| | | | satisfactory | | | | | | |

TABLE 2

| | | | | The difference between the first | | |
|---|---|---|---|---|---|---|
| | The difference between the first | | | angle a1 and the second angle | | |
| | angle a1 and the second angle | | | a2 is approximately equal | | |
| | a2 is less than 5 degrees. | | | to 5 degrees. | | |
| | Second | Expansion | | Second | Expansion | |
| | angle a2/ | distance | | angle a2/ | distance | |
| Spacing | first | L1/ | | first | L1/ | |
| L3 | angle | thickness | | angle | thickness | |
| (μm) | a1 | distance L2 | Result | a1 | distance L2 | Result |
| 15 | 52.8/51.1 | 2.9/4.6 | Poor | 46.8/52.1 | 1.9/3.5 | Barely |
| | | | | | | satisfactory |
| 20 | 52.3/52.5 | 2.5/4.2 | Poor | 48.1/53.9 | 1.7/3.2 | Qualified |
| 25 | 52.2/53.1 | 2.2/4.0 | Poor | 47.9/53.5 | 1.6/3.0 | Qualified |
| 30 | 51.9/52.5 | 1.8/3.3 | Barely | 48.3/53.8 | 1.4/2.6 | Qualified |
| | | | satisfactory | | | |
| 35 | 52.5/53.6 | 1.7/3.1 | Barely | 46.9/52.2 | 1.1/2.2 | Qualified |
| | | | satisfactory | | | |
| 40 | 53.2/52.8 | 1.8/2.9 | Barely | 47.4/52.5 | 1.1/2.3 | Qualified |
| | | | satisfactory | | | |
| 45 | 52.9/53.2 | 1.9/3.3 | Barely | 47.1/53.0 | 0.9/2.1 | Qualified |
| | | | satisfactory | | | |

As can be seen from Table 1 and Table 2 above, in the embodiments of the metal plates 10 with different thicknesses T (25±2 μm, 20±2 μm), no matter how the length of the spacing L3 changes, when the difference between the second angle a2 and the first angle a1 is less than 5 degrees, it is difficult to fully meet the expected results that the length-width ratio of the through-hole 2 is equal to 2.5, the thickness distance L2 of the through-hole 2 is less than 4 μm and the expansion distance L1 is less than 2 μm, so that the metal plates are judged as poor or barely satisfactory. Where, being judged as barely satisfactory refers to that the metal plate meets the expected results that the thickness distance L2 is less than 4 μm and the expansion distance L1 is less than 2 μm, but it is not accepted because of the error yield problem.

In Table 1, when the difference between the second angle a2 and the first angle a1 is set to be approximately equal to 5 degrees, it can be seen that the expected results that the length-width ratio of the through-hole 2 is equal to 2.5, the thickness distance L2 of the through-hole 2 is less than 4 μm and the expansion distance L1 is less than 2 μm can be produced when the thickness T of the metal plate 10 is 25±2 μm and the spacing L3 is between 30 μm and 45 μm, so that the results are judged as qualified, but the results are judged as poor or barely satisfactory if the spacing L3 is between 15 μm and 25 μm.

Similarly, in Table 2, when the difference between the second angle a2 and the first angle a1 is set to be approximately equal to 5 degrees, the expected results that the length-width ratio of the through-hole 2 is equal to 2.5, the thickness distance L2 of the through-hole 2 is less than 4 μm and the expansion distance L1 is less than 2 μm can be produced when the thickness T of the metal plate 10 is 20±2 μm and the spacing L3 is between 20 μm and 45 μm, so that the metal plates are judged as qualified, but the metal plates are judged as barely satisfactory if the spacing L3 is 15 μm.

Returning to Table 1, when the difference between the second angle a2 and the first angle a1 is set to be approximately equal to 10 degrees (greater than 5 degrees), the expected results that the length-width ratio of the through-hole 2 is equal to 2.5, the thickness distance L2 of the through-hole 2 is less than 4 μm and the expansion distance L1 is less than 2 μm can be produced when the thickness T of the metal plate 10 is 25±2 μm and the spacing L3 is between 15 μm and 25 μm, so that the metal plates are judged as qualified.

By comparing three groups of data with different differences between the second angle a2 and the first angle a1 in Table 1, and combining with several groups of experimental data with the spacing changing, it can be inferred that in Table 1, in the ranges that the difference between the second angle a2 and the first angle a1 is approximately equal to 10 degrees and the spacing L3 is greater than 25 μm, the expected results that the length-width ratio of the through-hole 2 is equal to 2.5, the thickness distance L2 of the through-hole 2 is less than 4 μm and the expansion distance L1 is less than 2 μm can be produced, thus actual data which are explicitly indicated in the lower-right few experimental results of Table 1 are omitted and only the word “qualified” is indicated in the result column.

From the above explanation of Table 1, it can be seen that, in the case of maintaining the shape ratio and the thickness T of the through-hole 2, if the difference between the second angle a2 and the first angle a1 is greater, the spacing L3 may be smaller and closer to 15 μm, in other words, the spacing L3 may be smaller if the difference between the second angle a2 and the first angle a1 is greater. The experimental results when the difference between the second angle a2 and the first angle a1 is approximately equal to 10 degrees (greater than 5 degrees) are not listed in Table 2, because under the condition that the difference between the second angle a2 and the first angle a1 is greater than 10 degrees in Table 2, the expectation that the thickness distance L2 of the through-hole 2 is less than 4 μm and the expansion distance L1 is less than 2 μm can be satisfied when the spacing L3 is 15 μm, and the table when the difference between the second angle a2 and the first angle a1 is greater than 10 degrees is omitted. There are no experimental examples in which the difference between the second angle a2 and the first angle a1 is greater than 10 degrees.

The two different groups of experimental results in Table 1 and Table 2 when the spacing L3 is 20 μm and the difference between the second angle a2 and the first angle a1 is approximately equal to 5 degrees are compared. From the results, it can be known that, under the same condition that the difference between the second angle a2 and the first angle a1 is approximately equal to 5 degrees, since the thickness T of the metal plate 10 in Table 2 is relatively low, the expectation that the thickness distance L2 of the through-hole 2 is less than 4 μm and the expansion distance L1 is less than 2 μm can be satisfied when the distance L3 is 20 μm. In other words, if the thickness of the metal plate 10 is small (e.g., 18 μm), the expected results should be satisfied when the difference between the second angle a2 and the first angle a1 is, for example, approximately equal to 5 degrees.

In addition, as can be seen from the above description, the phenomenon mentioned in the foregoing paragraphs that the second opening 23 has a larger expansion distance L1 in the long axis direction D1 is generated when the length-width ratio of the neck opening 22 is greater than 2.5, and the phenomenon is more obvious when the ratio is greater. Therefore, from the cause of the phenomenon and in cooperation with the description in Table 1 and Table 2 in which the length-width ratio is greater than 2.5, it is to be understood that, within the range of the thickness T of the metal plate 10 in Table 1 and Table 2, when the length-width ratio of the through-hole is equal to 2.5, the design that the second angle a2 is less than the first angle a1 can also satisfy the expectation that the thickness distance L2 is less than 4 μm and the expansion distance L1 is less than 2 μm. Similarly, when the length-width ratio of the through-hole 2 (neck opening 22) is greater than 3.5 (for example, when the ratio is 4.5), the second angle a2 should also be less than the first angle a1.

As explained above, the metal mask of the present invention has a plurality of through-holes with the length-width ratio equal to or greater than 2.5, the shapes of the first openings formed by the through-holes on the evaporation surface are designed, and the angle between the connecting line between the first short edge and the second short edge and the back surface on the evaporation surface side is less than the angle between the connecting line between the first long edge and the second long edge and the back surface, so that the influence of the shadow effect can be reduced when products are manufactured.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A metal mask, comprising:
a metal plate, having an evaporation surface and a back surface opposite to each other and a plurality of through-holes extending from the evaporation surface to the back surface, wherein each of the through-holes forms a first opening on the evaporation surface and forms a neck opening between the evaporation surface and the back surface, the first opening tapers towards the neck opening and has two opposite first long edges and two opposite first short edges, the two first short edges are connected between the two first long edges, the neck opening has two opposite second long edges and two opposite second short edges, the two second short edges are connected between the two second long edges, and a ratio of a length of the second long edge to a length of the second short edge is equal to or greater than 2.5;
wherein a first angle is formed between a connecting line between the first long edge and the second long edge and the back surface, a second angle is formed between a connecting line between the first short edge and the second short edge and the back surface, and the second angle is less than the first angle.

2. The metal mask as claimed in claim 1, wherein each of the through-holes forms a second opening on the back surface, an outline of the second opening corresponds to an outline of the neck opening so that the second opening has two opposite third long edges and two opposite third short edges, the second opening tapers towards the neck opening, and an opening size of the neck opening is less than opening sizes of the first opening and the second opening.

3. The metal mask as claimed in claim 2, wherein, in a direction along an opening direction of the through-hole, a thickness distance exists between the third short edge and the second short edge; in a direction perpendicular to the opening direction, an expansion distance exists between the third short edge and the second short edge; the thickness distance is less than or equal to 4 μm, and the expansion distance is less than or equal to 2 μm.

4. The metal mask as claimed in claim 2, wherein the through-holes are arranged along an extension direction parallel to the third long edge, a thickness of the metal plate is between 18 μm and 27 μm, and a spacing between two adjacent third short edges of two adjacent through-holes in the extension direction is between 15 μm and 45 μm.

5. The metal mask as claimed in claim 4, wherein the thickness is between 18 μm and 22 μm and the spacing is between 15 μm and 30 μm.

6. The metal mask as claimed in claim 1, wherein a difference between the second angle and the first angle is greater than or equal to 5 degrees.

7. The metal mask as claimed in claim 6, wherein the difference between the second angle and the first angle is between 5 degrees and 10 degrees.
